(19) United States
(12) Patent Application Publication
(10) Pub. No.: US 2014/0179082 A1
(43) Pub. Date: Jun. 26, 2014

(54) Selective Etching of Hafnium Oxide Using Non-Aqueous Solutions

(71) Applicant: INTERMOLECULAR INC., San Jose, CA (US)

(72) Inventors: John Foster, Mountain View, CA (US); Kim Van Berkel, Mountain View, CA (US)

(73) Assignee: INTERMOLECULAR INC., San Jose, CA (US)

(21) Appl. No.: 13/725,358

(22) Filed: Dec. 21, 2012

(51) Int. Cl. H01L 21/306; H01L 21/762

(52) U.S. Cl. CPC H01L 21/30604; H01L 21/76224
USPC 438/424; 438/703

(57) ABSTRACT

Provided are methods for processing semiconductor substrates having hafnium oxide structures as well as one or more of silicon nitride, silicon oxide, polysilicon, and titanium nitride structures. Selected etching solution compositions and processing conditions provide high etching selectivity of hafnium oxide relative to these other materials. As such, hafnium oxide structures may be partially or completely removed without significant damage to other exposed structures made from these other materials. In some embodiments, the etching rate hafnium oxide is two or more times greater than the etching rate of silicon oxide and/or twenty or more times greater that the etching rate of polysilicon. The etching rate of hafnium oxide may be one and half times greater than the etching rate of silicon nitride and/or five or more times greater than the etching rate of titanium nitride.

### BACKGROUND

Semiconductor devices have dramatically decreased in size in the last few decades. Modern devices include features that are 45 nanometers in size, 32 nanometers in size, and even smaller features. As device and feature sizes continue to shrink, processing methods need to be improved.

Hafnium oxide films have various uses in semiconductor devices. Hafnium oxides are considered as replacements for silicon oxides in field effect transistors (FETs), such as metal oxide semiconductor field effect transistors (MOSFETs). Use of hafnium oxides for this application is believed to reduce power consumption due to gate current leakage. Hafnium oxides are also considered for optical coating and memory applications.

Hafnium oxide components often need to be etched without damaging other components, which may be made from silicon nitride, silicon oxide, titanium nitride, and polysilicon. For example, when hafnium oxide is used as a gate oxide, an initially formed hafnium oxide structure may need to be undercut to allow uniform deposition of a liner and spacers. At the same time, adjacent silicon oxide and/or silicon nitride structures should not be impacted or be minimally impacted. Wet etching is a common method widely used in the semiconductor industry for removing materials within complex integrated circuit structures. High selectivity levels are needed to ensure that one structure is partially of completely removed without damaging one or more other structures exposed to the same etching solution.

### SUMMARY

Provided are methods for processing semiconductor substrates having hafnium oxide structures as well as one or more of silicon nitride, silicon oxide, polysilicon, and titanium nitride structures. Selected etching solution compositions and processing conditions provide high etching selectivity of hafnium oxide relative to these other materials. As such, hafnium oxide structures may be partially or completely removed without significant damage to other exposed structures made from these other materials. In some embodiments, the etching rate hafnium oxide is two or more times greater than the etching rate of silicon oxide and/or twenty or more times greater that the etching rate of polysilicon. The etching rate of hafnium oxide may be one and half times greater than the etching rate of silicon nitride and/or five or more times greater than the etching rate of titanium nitride.

Non-aqueous etching solutions may be used in some embodiments. The etching solutions may include a highly diluted hydrofluoric acid in a polar organic solvent, such as ethylene glycol or propylene glycol. The concentration of the polar organic solvent may be at least about 90% by volume. Some water may be present in the solution, but the amount of water is substantially less than the amount of the polar organic solvent. For example, hydrofluoric acid may be provided as a water-based solution that includes about 49% by weight of hydrofluoric acid and about 51% by weight of water. One part of this water based solution may be mixed with 100-500 parts by volume of the polar organic solvent to form a non-aqueous etching solution. In some embodiments, the mixing proportions may be 1:100, 1:200, or 1:300. Etching may be performed at a temperature range of 25° C. to 60° C.

In some embodiments, a method for processing semiconductor substrates involves providing a semiconductor substrate that includes a first structure and a second structure. The first structure is formed from hafnium oxide, while the second structure is formed from one of silicon nitride, silicon oxide, polysilicon, or titanium nitride. In some embodiments, the substrate has one or more additional structures that include one of silicon nitride, silicon oxide, polysilicon, or titanium nitride. The materials of these one or more other structures may be different from the material of the second structure.

The method may proceed with exposing the semiconductor substrate or, more specifically, the first and second structures (and other structures, if such structures are present) to an etching solution including hydrofluoric acid and a polar organic solvent. The concentration of the polar organic solvent in the etching solution may be at least about 90% by volume or, more specifically, at least about 95% by volume or even at least about 98% by volume in some embodiments. The polar organic solvent may be one of ethylene glycol or propylene glycol. Some other examples of polar organic solvents include ethyl acetate, tetrahydrofuran, dichloromethane, acetone, acetonitrile, dimethylformamide, dimethyl sulfoxide. In some embodiments, the concentration of hydrofluoric acid in the etching solution is between 0.1% by volume and 10% by volume or, more specifically between 2% by volume and 4% by volume. In some embodiments, the etching solution includes some water, but the amount of water is substantially less than the amount of the polar organic solvent. For example, the concentration of water in the etching solution may be less than 4% by volume or, more specifically, less than 2% by volume. As such, the etching solution is considered to be non-aqueous. The etching solution may also include some hydrochloric acid, such as between about 5% % by volume and 15%% by volume. Hydrochloric acid may be used to adjust acidity (pH) of the solution.

The method may proceed with etching the first structure on the substrate, such that the etching rate of the first structure is greater than the etching rate of the second structure. In some embodiments, the etching rate of the first structure is at least 1.5 times greater than the etching rate of the second structure or, more specifically, the etching rate of the first structure is at least two times greater than the etching rate of the second structure. In some embodiments, the etching rate of the first structure may be five times greater and even twenty times greater than the etching rate of the second structure. This ratio of the etching rates is sometimes referred to as etching selectivity. Etching selectivity depends on the etched materials, composition of the etching solution, temperature of the etching solution, and other factors as further described below. The upper bound for etching selectivity values may be 1000 in some embodiments.

The etching rate of the first structure is between 10 Angstroms per minute and 200 Angstroms per minute or, more specifically, between 50 Angstroms per minute and 200 Angstroms per minute. While high etching rates may be desirable during complete removal of the first structure, the etching rate may need to be limited for process control reasons when partial etching is used. Furthermore, factors affecting etching rates often influence other parameters, such as selectivity. The etching solution may be maintained at a temperature of between 25° C. and 60° C. at least during etching of the first structure. For example, the etching solution may be maintained at a temperature of 40° C. at least during etching of the first structure.

In some embodiments, the second structure is formed by depositing silicon nitride using plasma enhanced chemical vapor deposition (PECVD) or low pressure chemical vapor deposition (LPCVD). Deposition techniques may impact etching rates and, as a result, etching selectivity of various materials. In some embodiments, the first structure is a gate oxide. The second structure may be a shallow trench isolation (STI) structure. In some embodiments, the first structure is only partially removed during etching of the first structure. Alternatively, the first structure may be completely removed during etching of the first structure. In this situation, a structure underlying the first structure may be made from material that is substantially inert to the etching solution. In some embodiments, this underlying structure is formed from one of silicon nitride, silicon oxide, polysilicon, or titanium nitride.

In some embodiments, a method for processing semiconductor substrates involves providing a semiconductor substrate having a first structure formed from hafnium oxide and a second structure formed from silicon oxide. The method may proceed with exposing the semiconductor substrate to an etching solution including hydrofluoric acid and ethylene glycol. The etching solution is maintained at a temperature of about 25° C. to 60° C. The concentration of ethylene glycol in the etching solution is at least about 95% by volume. The method continues with partially etching the first structure such that the etching rate of the first structure is at least twice greater than the etching rate of the second structure and such that the etching rate of the first structure is at least about 50 Angstroms per minute.

In some embodiments, a method for processing semiconductor substrates involves providing a semiconductor substrate including a first structure formed from hafnium oxide and a second structure formed from polysilicon. The method may proceed with exposing the semiconductor substrate to an etching solution including hydrofluoric acid, water, and ethylene glycol. The concentration of ethylene glycol in the etching solution is at least about 90% by volume, while the concentration of water in the solution is less than about 4% by volume. The method continues with etching the first structure such that the etching rate of the first structure is at least twenty times greater than the etching rate of the second structure.

These and other embodiments are described further below with reference to the figures.

### BRIEF DESCRIPTION OF THE DRAWINGS

FIGS. 1A and 1B illustrate schematic representations of semiconductor substrate portions before and after etching, in accordance with some embodiments.

FIG. 2 illustrates a process flowchart corresponding to a method of processing a semiconductor substrate to at least partially remove hafnium oxide structures from the substrate including other structures, in accordance with some embodiments.

FIG. 3A illustrates a plot of hafnium oxide to silicon oxide etching selectivity as a function of an etching solution temperature, in accordance with some embodiments.

FIG. 3B illustrates a plot of etched thicknesses as a function of etching duration for five different materials exposed to the same etching solution and under the same processing conditions, in accordance with some embodiments.

FIG. 4 illustrates a schematic representation of an etching apparatus for processing a semiconductor substrate to remove hafnium oxide structures from the surface of the substrate, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### INTRODUCTION

Scaling of the gate lengths and equivalent gate oxide thicknesses is forcing the replacement of silicon dioxide as a gate dielectric by materials having high-dielectric constants (i.e., high-k materials). The goals include reduction of leakage currents and meeting requirements of reliability. Some additional consideration in selecting suitable replacement materials include silicon related band offsets, permittivity, dielectric breakdown strength, interface stability and quality with silicon, and the carrier effective masses.

Hafnium dioxide is a leading candidate for silicon dioxide replacement as a gate dielectric material. It has a dielectric constant of about 25 at room temperature or about six times greater than that of silicon dioxide. While this dielectric constant is more than an order of magnitude smaller than for strontium titanium oxide (SrTiO₃), which has a dielectric constant of about 300, hafnium oxide has a conduction band offset of about 1.5-2.0 eV with respect to silicon, which is more than one order of magnitude higher than that of strontium titanium oxide.

The same properties of hafnium oxide that make it a leading candidate for a gate dielectric application also give hafnium oxide a high potential for other applications, such as insulating dielectrics in capacitive elements of various memory devices or, more specifically, of dynamic random-access memory (DRAM) capacitor stacks. Because of its high dielectric constants, a thick film of hafnium oxide can be used to achieve the same performance as a much thinner silicon dioxide layer. However, thicker hafnium oxide films have much lower leakage currents in comparison with thinner silicon oxide layers. In addition to having a high dielectric constant, hafnium oxide is thermodynamically stable with respect to silicon, with which it may be in contact in many semiconductor applications. Many modern complementary metal-oxide-semiconductor (CMOS) and DRAM processes involve high temperatures (e.g., 1000° C.) that are applied to substrates for a few seconds. Some other applications of hafnium oxide include optical coatings, catalysts, and protective coatings (due to its hardness and thermal stability).

Hafnium oxide layers or structures may be deposited by a variety of physical vapor deposition (PVD) methods, including laser pulse ablation and sputtering. Other deposition techniques include CVD using β-diketonate precursors, alkoxide precursors, and chloride precursors. Atomic layer deposition (ALD) techniques may be used to prepare films using both chloride and iodide precursors. Different deposition techniques yield different film structures that may have different susceptibilities to etching.

Provided are methods for processing semiconductor substrates having hafnium oxide structures or, more specifically, methods for at least partial removal of the hafnium oxide structures using etching solutions while preserving other structures provided on the same substrate. For purposes of this disclosure, full or partial removal of the hafnium oxide structures is collectively referred to as etching. The difference between full or partial removal depends on the size and shape of the structure, etching rate, and etching duration. A hafnium oxide structure may be used as a gate dielectric, a high-k dielectric in DRAM capacitors, and other like devices.

In addition to hafnium oxide, the surface exposed to the etching solution includes one or more of silicon nitride, silicon oxide, polysilicon, or titanium nitride structures. For example, a method may be used to partially remove a hafnium oxide gate dielectric, which involves exposing silicon oxide STI structures to the same etching solution. Etching solutions and processing conditions described herein provide high etching selectivity of hafnium oxide relative to these other materials. As such, hafnium oxide structures may be partially or completely removed without significant deterioration of other exposed structures. In some embodiments, etching selectivity of hafnium oxide relative to silicon oxide is greater than 2 (e.g., between about 2 and 10), while selectivity of hafnium oxide relative to polysilicon is greater than 20 (e.g., between about 20 and 100). Etching selectivity of hafnium oxide relative to silicon nitride may be greater than 1.5 (e.g., between about 1.5 and 50), while etching selectivity of hafnium oxide relative to titanium nitride may be greater than 5 (e.g., between about 5 and 100).

In some embodiments, etching rates of hafnium oxide may be at least about 10 Angstroms per minute or, more specifically, at least about 50 Angstroms per minute, and even greater. However, extremely high etching rates (e.g., greater than 200 Angstroms per minute or greater than 500 Angstroms per minute) may need to be avoided, particularly when only partial removal of hafnium oxide structures is performed. High etching rates make process control difficult.

Non-aqueous solutions are used for selective etching of hafnium oxides. For purposes of this disclosure, a non-aqueous solution is defined as a solution that has predominantly a non-aqueous solvent. The non-aqueous solution may include some water but the amount of water is substantially less (e.g., ten times less) that the amount of the non-aqueous solvent. For example, the concentration of water in the etching solution may be less than 4% by volume and even less than 2% by volume. A polar organic solvent, such as ethylene glycol or propylene glycol, may be used as a non-aqueous solvent. The concentration of the polar organic solvent may be at least about 90% by volume or even at least about 95% by volume.

The non-aqueous solution also includes hydrofluoric acid. The concentration of hydrofluoric acid in the etching solution may be between 0.1% by volume and 10% by volume or, more specifically between 2% by volume and 4% by volume. In some embodiments, hydrofluoric acid is provided as a water-based solution that includes about 49% by volume of hydrofluoric acid and about 51% by volume of water. One part of this water based solution may be mixed with 100-500 parts by volume of the polar organic solvent to form the non-aqueous etching solution. In some embodiments, the mixing proportions are 1:100, 1:200, 1:300, or 1:500.

### Semiconductor Device Examples

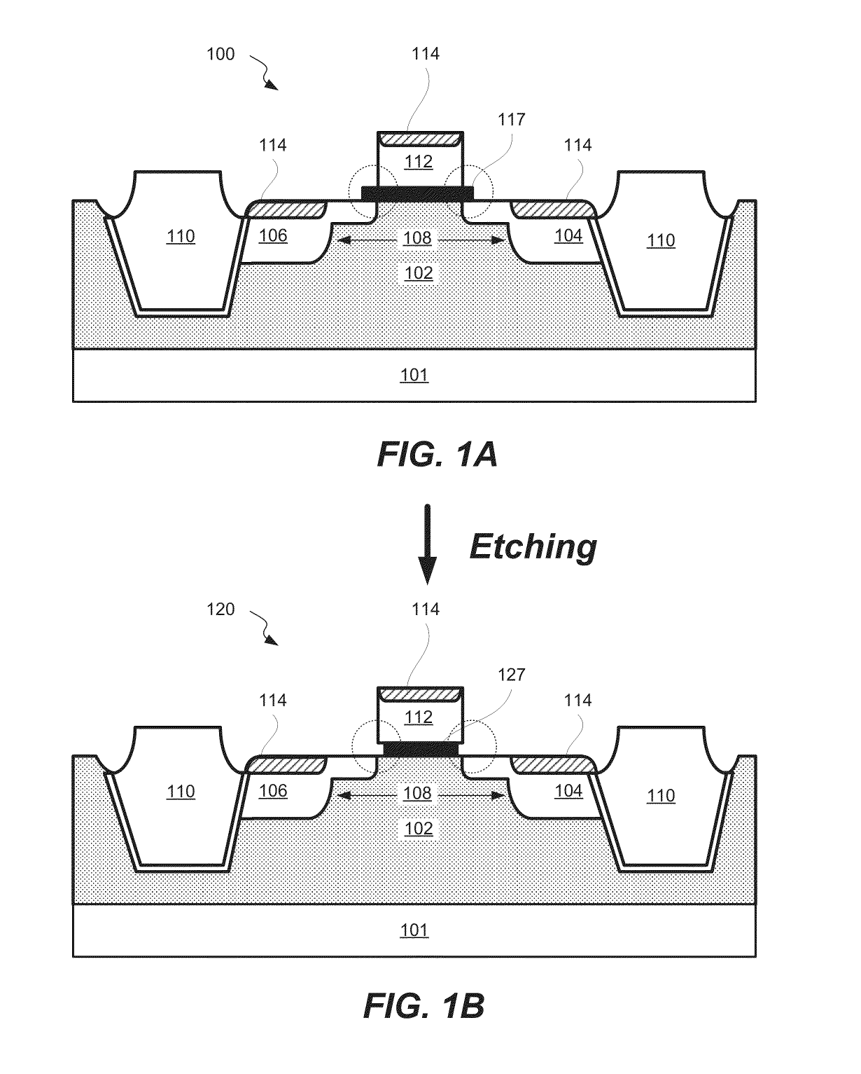

A brief description of semiconductor device examples is presented below to provide better understanding of various hafnium oxide etching and selectivity features. Specifically, FIGS. 1A and 1B illustrate schematic representations of substrate portions including MOS device 100 before partial removal of gate dielectric 117 and the same device 120 after such partial removal, in accordance with some embodiments. The references below are made to positive metal-oxide semiconductor (PMOS) devices but other types of MOS devices can be used in the described processes and will be understood by one having ordinary skill in the art. MOS device 100 includes a p-doped substrate 101 and an n-doped well 102 disposed within substrate 101. Substrate 101 is typically a part of an overall wafer that may include other devices. Some of these devices may include silicon nitride, silicon oxide, polysilicon, or titanium nitride structures that are exposed to an etching solution during partial removal of gate dielectric 117. P-doped substrate 101 may include any suitable p-type dopants, such as boron and indium, and may be formed by any suitable technique. N-doped well 102 may include any suitable n-type dopants, such as phosphorus and arsenic, and may be formed by any suitable technique. For example, n-doped well 102 may be formed by doping substrate 101 by ion implantation, for example.

MOS device 100 also includes a conductive gate electrode 112 that is separated from n-doped well 102 by gate dielectric 117. Gate electrode 112 may include any suitable conductive material. In one embodiment, gate electrode 112 may comprise polysilicon. In another embodiment, gate 112 may include polysilicon doped with a p-type dopant, such as boron. Gate dielectric 117 is formed from hafnium oxide. Hafnium oxide has a very high a dielectric constant and a large conduction band offset with respect to silicon as described above.

MOS device 100 also includes p-doped source region 104 and drain region 106 (or simply the source and drain) disposed in n-doped well 102. Source 104 and drain 106 are located on each side of gate electrode 112 forming channel 108 within n-doped well 102. Source 104 and drain 106 may include a p-type dopant, such as boron. Source 104 and drain 106 may be formed by ion implantation. After forming source 104 and drain 106, MOS device 100 may be subjected to an annealing and/or thermal activation process, which may impact etching characteristics of various components.

In some embodiment, source 104, drain 106, and gate electrode 112 are covered with a layer of self-aligned silicide portions 114, which may be also referred to as salicide portions or simply salicides. For example, a layer of cobalt may be deposited as a blanket film and then thermally treated to form these silicide portions 114. Other suitable materials include nickel and other refractory metals, such as tungsten, titanium, After forming the blanket film from the suitable metal, the film is subjected to rapid thermal process (RTP) to react the metal with silicon contained within gate electrode 112, as well as within source 104 and drain 106, to form a metal silicide. The RTP process may be performed at 700° C. to 1000° C.

MOS device 100 may also include STI structures 110 disposed on both sides of source 104 and drain 106. STI structures 110 may include liners formed on the side and bottom walls by, for example, thermal oxidation of silicon of n-doped well 102. The main body of STI structures is formed by filling a trench within n-doped well 102 with a dielectric material, such as silicon oxide. Silicon oxide may be filled using high density plasma (HDP) deposition process.

As shown in FIG. 1A, gate dielectric 117 may protrude beyond gate electrode 112. As such, gate dielectric 117 may need to be partially etched such that it does not extend past electrode 112 and does not interfere with subsequent formation of liners and spacers on sidewalls of gate electrode 112. However, exposing portions of gate dielectric 117 to an etching solution will also expose other components, such as gate electrode 112 (which may be formed from polysilicon), STI structures (which may be formed from silicon oxide), as well as other structures (which may be formed from silicon nitride, silicon oxide, polysilicon, and/or titanium nitride). Etching of these components may need to be minimized.

FIG. 1B illustrates a schematic representation of MOS device 120 after partial removal of the gate dielectric 117, in accordance with some embodiments. Edges of a trimmed gate dielectric 127 (formed from gate dielectric 117) have been trimmed such that gate dielectric 127 does not extend away from gate electrode 112. MOS device 120 is ready for receiving a liner and spacers on the side walls of gate electrode 112 and over portions of source region 104 and drain region 106.

Other devices that include hafnium oxide structures and one or more structures formed from one of silicon nitride, silicon oxide, polysilicon, or titanium nitride are also within the scope of this disclosure. For example, a DRAM capacitor stack including a hafnium oxide dielectric and one or more electrodes formed from titanium nitride and/or doped polysilicon may be etched using techniques described herein.

### Processing Examples

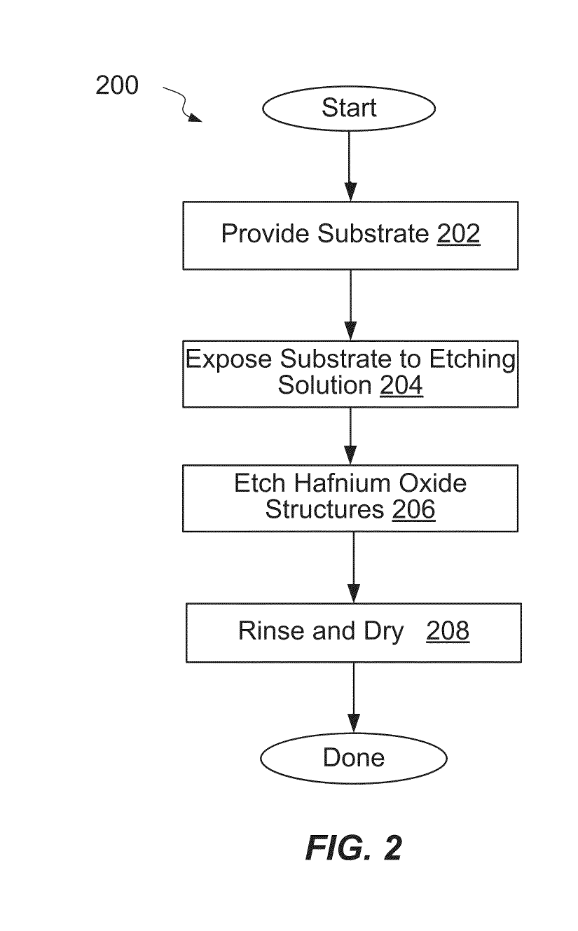

FIG. 2 illustrates a process flowchart corresponding to method 200 of processing a semiconductor substrate to at least partially remove hafnium oxide structures, in accordance with some embodiments. Method 200 may commence with providing a semiconductor substrate including a hafnium oxide structure (e.g., a first structure) and another structure formed from one of silicon nitride, silicon oxide, polysilicon, or titanium nitride (e.g., a second structure) during operation 202. Some substrate examples are described above with reference to FIGS. 1A and 1B. In some embodiments, the substrate has one or more additional structures (e.g., a third structure, a fourth structure) that include one of silicon nitride, silicon oxide, polysilicon, or titanium nitride. The materials of these other structures may be different from the material of the second structures. In some embodiments, one of the structures on the provided substrate is formed by depositing silicon nitride using PECVD or LPCVD. Deposition techniques may impact etching rates and, as a result, etching selectivity of various materials.

Method 200 may proceed with exposing the semiconductor substrate to an etching solution during operation 204. Specifically, the etching solution comes in contact with the hafnium oxide and the other structure. As stated above, the etching solution may include hydrofluoric acid diluted in a polar organic solvent. In some embodiments, the concentration of hydrofluoric acid in the etching solution is between 0.1% by volume and 10% by volume or, more specifically between 2% by volume and 4% by volume. Sometimes, these levels of dilution are referred to as a highly diluted solution. The concentration of the polar organic solvent in the etching solution may be at least about 90% by volume or, more specifically, at least about 95% by volume or even at least about 98% by volume in some embodiments. The polar organic solvent may be one of ethylene glycol or propylene glycol. Some other examples of polar organic solvents include ethyl acetate, tetrahydrofuran, dichloromethane, acetone, acetonitrile, dimethylformamide, dimethyl sulfoxide, acetic acid, n-butanol, isopropanol, n-propanol, ethanol, methanol, and formic acid. In some embodiments, the etching solution includes some water, but its amount is substantially less than the amount of the polar organic solvent. For example, the concentration of water in the etching solution may be less than 4% by volume or, more specifically, less than 2% by volume.

The etching solution may be maintained at a temperature of between 25° C. and 60° C. at least during etching of the first structure. For example, the etching solution may be maintained at a temperature of 40° C. at least during etching of the first structure. While higher temperatures may result in faster etching, etching selectivity may be compromised. Furthermore, faster etching may be undesirable when hafnium oxide structures are being only partially etched, and the etched amounts need to be specifically controlled.

In some embodiments, prior to exposing the substrate to the etching solution during operation 204, one or more pretreatment operations may be performed such as chemical oxidation or plasma nitridation. These pretreatment operations may be specifically designed to increase etching selectivity of hafnium oxide structures relative to other structures. A pretreatment operation may be used to build a protective layer over these other structures (e.g., silicon nitride structures, silicon oxide structures, titanium nitride structures, and polysilicon structures).

Method 200 may proceed with etching the hafnium oxide structure during operation 206. The hafnium oxide etching rate may be greater than the etching rate of the other structures. In some embodiments, the etching rate of hafnium oxide is at least 1.5 times greater than the etching rate of at least one other structure or, more specifically, twice greater. The etching rate of hafnium oxide is between 10 Angstroms per minute and 200 Angstroms per minute or, more specifically, between 50 Angstroms per minute and 200 Angstroms per minute. In some embodiments, the etching rate of hafnium oxide is substantially constant (e.g., varies less than 25% over time).

Operation 206 may proceed for a predetermined period of time to ensure removal of the desired amount of hafnium oxide. In some embodiments, the hafnium oxide structure is only partially removed. Alternatively, the hafnium oxide structure may be removed completely. In this latter case, another structure positioned under the hafnium oxide structure may be made from a material that is more resistant to the etching solution than hafnium oxide. This feature ensures that the other structure is not substantially deteriorated by the etching solution once the hafnium oxide structure is completely removed.

After completion of operation 206, method 200 may proceed with rinsing and drying the substrate during operation 208. The residual etching solution is removed from the substrate surface during this operation by, for example, rinsing the surface with deionized water and drying with an inert gas, such as nitrogen or argon.

### Experimental Results

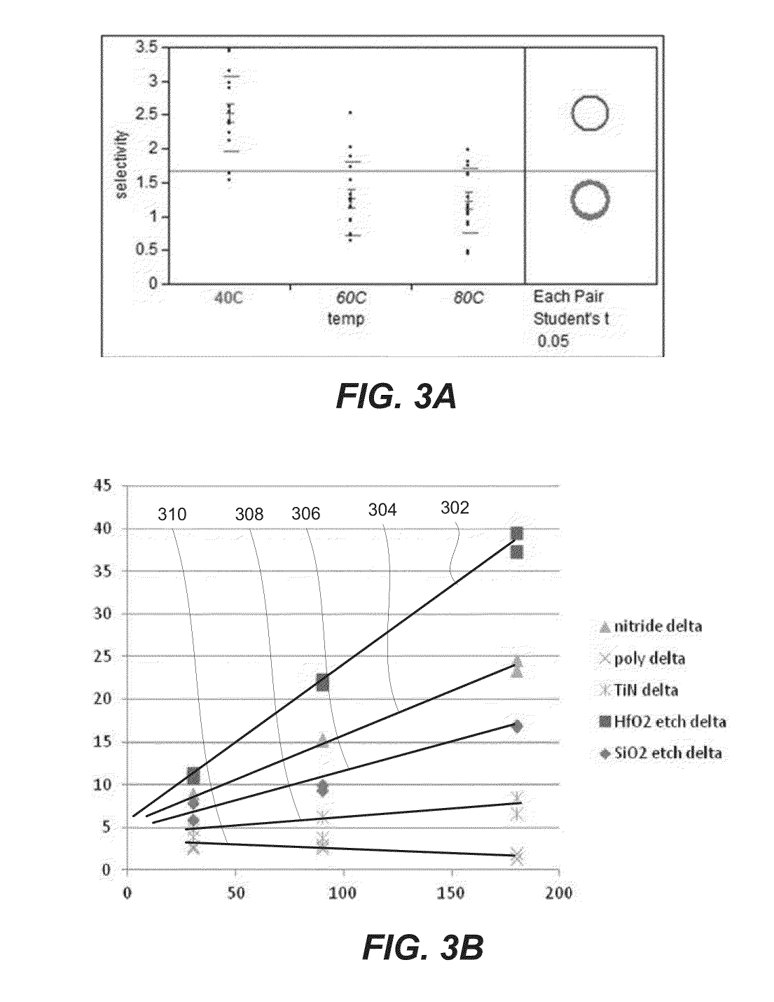

Various experiments have been conducted to determine effects of different processing conditions and etching solutions on selectivity and etching rates. FIG. 3A illustrates a plot of hafnium oxide to silicon oxide etching selectivity as a function of the etching solution temperature, in accordance with some embodiments. Test samples were exposed to the same ethylene glycol based etching solution having between 0.5% and 4% by volume of hydrofluoric acid. The solution was maintained at 40° C., 60° C. and 80° C. Each test sample included a hafnium oxide structure and a silicon oxide structure. The selectivity was estimated based on reduction in the thicknesses of both structures. The best selectivity (i.e., 2.5 on average) was achieved with the etching solution maintained at 40° C. The selectivity of the etching solution maintained at 60° C. was 1.26 on average, while the selectivity of the etching solution maintained at 80° C. was 1.23 on average. Overall, it has been determined that temperature has a significant effect on etching selectivity (at least on hafnium oxide to silicon oxide selectivity). While lower temperatures may be often selected from the selectivity standpoint, these temperatures sometimes may correspond to unreasonably low etching rates. As a result, higher temperatures may be used despite some losses in selectivity.

A similar experiment was conducted to determine effects of a hydrofluoric acid concentration on etching selectivity. An initial mixture containing 49% by volume of hydrofluoric acid and 51% by volume of water was diluted in accordance with the following proportions: 1 part of the initial mixture per 25 parts of ethylene glycol (i.e., 1:25 solution), 1 part of the initial mixture per 50 parts of ethylene glycol (i.e., 1:50 solution), 1 part of the initial mixture per 100 parts of ethylene glycol (i.e., 1:100 solution), and 1 part of the initial mixture per 200 parts of ethylene glycol (i.e., 1:200 solution). A set of test samples, each containing a hafnium oxide structure and a silicon oxide structure, was submerged into these solutions to determine an etching selectivity of these different solutions. Average selectivity values are presented in the table below.

TABLE

| Solution | Average Selectivity |
|---|---|
| 1:25 | 1.52 |
| 1:50 | 1.86 |
| 1:100 | 1.72 |
| 1:200 | 1.62 |

These results indicate that the concentration of hydrofluoric acid does not have a major impact on selectivity, at least in comparison to the temperature of the solution.

FIG. 3B illustrates a plot of etched thicknesses (i.e., thickness reduction) as a function of etching duration for five different materials, in accordance with some embodiments. All tests were conducted using the 25:1 solution described above at 40° C. Line 302 represents hafnium oxide samples, line 304 represents silicon nitride samples, line 306 represents silicon oxide samples, line 308 represents titanium nitride samples, and finally line 310 represents polysilicon samples. The slope of each line corresponds to the etching rates of these samples. The hafnium oxide, silicon nitride and silicon oxide samples show very consistent etching rates (i.e., repeatable data points and constant slope).

### Apparatus Examples

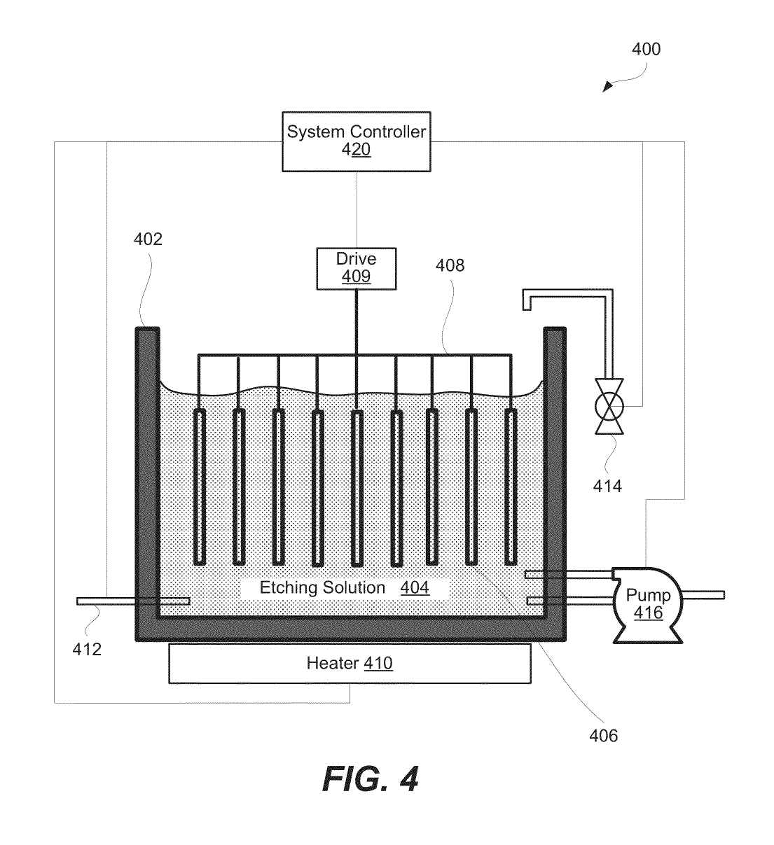

FIG. 4 illustrates a schematic representation of etching apparatus 400 for processing a semiconductor substrate to selectively remove hafnium oxide from the surface of the substrate, in accordance with some embodiments. For clarity, some components of apparatus 400 are not included in this figure. Apparatus 400 includes bath 402 for containing etching solution 404. One or more semiconductor substrates 406 may be submerged into etching solution 404 for processing or, more specifically, for removal of silicon nitride structures. Substrate 406 may be supported by substrate holder 408, which may be attached to drive 409 for moving substrate holder 408. Specifically, substrate holder 408 may be moved to submerge substrates 406 into etching solution 404 for processing, remove substrates 406 from etching solution 404 after processing, and/or to move substrates 406 within etching solution 404 during processing (e.g., to agitate etching solution 404).

Apparatus 400 also includes heater 410 and temperature sensor 412 (e.g., a thermocouple) for maintaining etching solution 404 at a predetermined temperature. Heater 410 and temperature sensor 412 may be connected to system controller 420, which may control power supplied to heater 410 based on signals received from temperature sensor 412. Various features of system controller 420 are described below.

Apparatus 400 may also include a liquid delivery system 414 for supplying additional liquids and controlling the composition of etching solution 404. For example, some components of etching solution 404 may evaporate from bath 402, and these components may be replenished in bath 402 by liquid delivery system 414. Liquid delivery system 414 may be connected to and controlled by system controller 420. Various sensors (e.g., conductivity sensor, weight sensor) may be used to provide signals about potential changes in composition of etching solution 404. Apparatus 400 may be also equipped with pump 416 for recirculating etching solution 404 in bath 402 and other purposes. Pump 416 may be also connected to and controlled by system controller 420.

Apparatus 400 may include system controller 420 for controlling process conditions during silicon nitride etching processes. Controller 420 may include one or more memory devices and one or more processors with a central processing unit (CPU) or computer, analog and/or digital input/output connections, stepper motor controller boards, and the like. In some embodiments, controller 420 executes system control software including sets of instructions for controlling timing of operations, temperature of etching solution 404, composition of etching solution 404, and other parameters. Other computer programs and instruction stored on memory devices associated with controller may be employed in some embodiments.

### CONCLUSION

Although the foregoing concepts have been described in some detail for purposes of clarity of understanding, it will be apparent that some changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method for processing semiconductor substrates, the method comprising:
providing a semiconductor substrate comprising a first structure and a second structure, the first structure comprising hafnium oxide, the second structure comprising one of silicon nitride, silicon oxide, polysilicon, or titanium nitride;
exposing the semiconductor substrate to an etching solution comprising hydrofluoric acid and a polar organic solvent,
wherein the concentration of the polar organic solvent in the etching solution is at least 90% by volume; and
etching the first structure,
wherein an etching rate of the first structure is greater than an etching rate of the second structure.

2. The method of claim 1, wherein the etching rate of the first structure is at least 1.5 times greater than the etching rate of the second structure.

3. The method of claim 1, wherein the etching rate of the first structure is at least two times greater than the etching rate of the second structure.

4. The method of claim 1, wherein the polar organic solvent comprises one of ethylene glycol or propylene glycol.

5. The method of claim 1, wherein the concentration of hydrofluoric acid in the etching solution is between 0.1% by volume and 10% by volume.

6. The method of claim 1, wherein the concentration of hydrofluoric acid in the etching solution is between 2% by volume and 4% by volume.

7. The method of claim 1, wherein the etching solution further comprises water.

8. The method of claim 7, wherein a concentration of water in the etching solution is less than 4% by volume.

9. The method of claim 7, wherein a concentration of water in the etching solution is less than 2% by volume.

10. The method of claim 1, wherein the etching rate of the first structure is between 10 Angstroms per minute and 200 Angstroms per minute.

11. The method of claim 1, wherein the etching rate of the first structure is between 50 Angstroms per minute and 200 Angstroms per minute.

12. The method of claim 1, wherein the etching solution is maintained at a temperature of between 25° C. and 60° C. during etching of the first structure.

13. The method of claim 1, wherein the etching solution is maintained at a temperature of 40° C. during etching of the first structure.

14. The method of claim 1, wherein the second structure is formed by depositing silicon nitride using plasma enhanced chemical vapor deposition (PECVD).

15. The method of claim 1, wherein the second structure is formed by depositing silicon nitride using low pressure chemical vapor deposition (LPCVD).

16. The method of claim 1, wherein the first structure is a gate oxide.

17. The method of claim 1, wherein the second structure is a shallow trench isolation (STI) region.

18. The method of claim 1, wherein the first structure is only partially removed during etching of the first structure.

19. A method for processing semiconductor substrates, the method comprising:
providing a semiconductor substrate comprising a first structure and a second structure, the first structure comprising hafnium oxide, the second structure comprising silicon oxide;
exposing the semiconductor substrate to an etching solution comprising hydrofluoric acid and ethylene glycol, the etching solution maintained at a temperature of 25° C. to 60° C.,
wherein a concentration of ethylene glycol in the etching solution is at least 95% by volume; and
partially etching the first structure,
wherein an etching rate of the first structure is at least twice greater than an etching rate of the second structure and is at least 50 Angstroms per minute.

20. A method for processing semiconductor substrates, the method comprising:
providing a semiconductor substrate comprising a first structure and a second structure,
the first structure comprising hafnium oxide,
the second structure comprising polysilicon;
exposing the semiconductor substrate to an etching solution comprising hydrofluoric acid, water, and ethylene glycol,
wherein a concentration of ethylene glycol in the etching solution is at least 90% by volume and concentration of water in the etching solution is less than 4% by volume; and
etching the first structure,
wherein an etching rate of the first structure is at least twenty times greater than an etching rate of the second structure.
